(19) United States
(12) Patent Application Publication
(10) Pub. No.: US 2012/0127663 A1
(43) Pub. Date: May 24, 2012

(54) ELECTRONIC DEVICE

(75) Inventors: Hiroyuki MOCHIZUKI, Kawasaki (JP); Masao HONDA, Hyogo (JP)

(73) Assignee: FUJITSU LIMITED, Kawasaki (JP)

(21) Appl. No.: 13/361,297

(22) Filed: Jan. 30, 2012

Related U.S. Application Data
(63) Continuation of application No. PCT/JP2009/065218, filed on Aug. 31, 2009.

(51) Int. Cl. H05K 7/20

(52) U.S. Cl. 361/692

(57) ABSTRACT

An electronic device includes a case having a first surface facing a second surface and a side surface along peripheries of the first and second surfaces to form an internal space, an electronic component adjacent to a first side part of the side surface with a gap between the electronic component and the first side part, and a circuit board extending along the first surface and distant from the first surface such that the electronic component is sandwiched between the circuit board and the first surface. The case includes an air intake port introducing air into the case and an air outlet port discharging air flowed along the electronic component, and the circuit board includes a vent opening including a first end portion extending to a position closer to the first side part than a first end of the electronic component facing the first side part of the case.

### CROSS-REFERENCE TO RELATED APPLICATIONS

The present application is a U.S. continuation application filed under 35 USC 111(a) claiming benefit under 35 U.S.C. 120 and 365(c) of PCT International application No. PCT/JP2009/065218 filed on Aug. 31, 2009, the entire contents of which are incorporated herein by reference.

### FIELD

The disclosures herein are related to an electronic device such as a notebook computer.

### BACKGROUND

Owing to the demand for downsizing electronic devices, the electronic devices such as notebook computers (hereinafter referred to as “notebook PCs”) include numerous electronic components tightly arranged in their cases having almost no space between the electronic components. The notebook PCs generally include a built-in hard disk drive (hereinafter simply called a “HDD”). The HDD is an electronic component configured to magnetically record information on a disc-like hard disk or retrieve the information magnetically recorded on the hard disk drive while rotating the hard disk. Since the HDD incorporates a motor that generates heat, it is necessary to cool the generated heat. A case of the notebook PC (or a notebook PC case) includes built-in heat-generating electronic components such as a CPU chip and the like other than the HDD, and hence the notebook PC case further includes a built-in fan configured to cool such heat-generating electronic components. The HDD may be cooled by utilizing the airflow generated by the fan. However, numerous electronic components are tightly arranged inside the notebook PC case. Accordingly, if the notebook PC has a layout in which a printed circuit board (main board) having a wide area is arranged immediately adjacent to the HDD, there may not be sufficient space in the notebook PC case for allowing sufficient airflow to flow along the HDD.

There is proposed a technology known in the art in which a through-hole is formed in the printed circuit board, which allows the airflow to flow through the printed circuit board. However, there is no disclosure illustrating a configuration to efficiently cool the tightly arranged electronic components such as the HDD in the notebook PC case.
Patent Document 1: WO 02/009113
Patent Document 2: Japanese Laid-open Patent Publication No. 2008-251067
Patent Document 3: Japanese Laid-open Patent Publication No. 2005-166777

### SUMMARY

According to an aspect of the embodiment, there is provided an electronic device that includes a case having a first surface facing a second surface and a side surface formed along peripheries of the first surface and the second surface, the first surface, the second surface and the side surface forming an internal space of the case; an electronic component arranged inside the case at a position adjacent to a first side part of the side surface of the case, a gap being provided between the electronic component and the first side part; and a circuit board extending along the first surface of the case to include a position adjacent to or in contact with the first side part of the case, the circuit board having a distance from the first surface of the case such that the electronic component is sandwiched between the circuit board and the first surface of the case. In the electronic device, the case includes an air intake port configured to introduce air into the case, the air intake port being formed in the first side part of the side surface at a position closer to the first surface thereof than the circuit board, and an air outlet port configured to discharge from the case the introduced air having flowed along the electronic component. Further, in the electronic device, the circuit board includes a first vent opening including a first end portion extending to a position closer to the first side part of the case than a first end of the electronic component facing the first side part of the case.

The object and advantages of the invention may be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is an external perspective view illustrating a convertible notebook PC in an open state as an electronic device according to an embodiment;

FIG. 2 is an external perspective view illustrating a main body unit of a notebook PC as an electronic device according to a comparative example viewing from a top surface;

FIG. 3 is a bottom side perspective view illustrating the main body unit of the notebook PC according to the comparative example in FIG. 2;

FIG. 4 is a perspective view illustrating a main board contained as one of internal components and various components fixed to the main board arranged in the main body unit of the notebook PC according to the comparative example in FIG. 3;

FIG. 5 is a bottom view illustrating the main body unit of the notebook PC according to the comparative example;

FIG. 6 is a cross sectional view illustrating the main body unit of the notebook PC taken along a VI-VI dashed-dotted arrow of FIG. 5;

FIG. 7 is an enlarged view of a part specified by a circle R in FIG. 6;

FIG. 8 is a perspective view illustrating a top surface and a bottom surface of a main body unit of the notebook PC according to the embodiment the external view of which is illustrated in FIG. 1;

FIG. 9 is a perspective view illustrating the top surface and the bottom surface of the main body unit of the notebook PC according to the embodiment the external view of which is illustrated in FIG. 1;

FIG. 10 is an enlarged view illustrating a part including a HDD and a fan taken from the main body unit of the notebook PC according to the embodiment illustrated in FIG. 1;

FIG. 11 is a view illustrating a main board and various components fixed to the main board as one of internal components arranged in the main body unit of the notebook PC according to the embodiment;

FIG. 12 is a bottom view illustrating the main body unit of the notebook PC according to the embodiment;

FIG. 13 is a cross sectional view illustrating the main body unit of the notebook PC taken along a XIII-XIII dashed-dotted arrow of FIG. 12;

FIG. 14 is an enlarged view of a part specified by a circle R in FIG. 13;

FIG. 15 is a schematic view illustrating airflow in the cross sections of the main body unit of the notebook PC according to the embodiment illustrated in FIGS. 13 and 14;

FIG. 16 is a view illustrating a bottom surface of the HDD;

FIG. 17 is a view illustrating an area in which the HDD is arranged inside a case of the main body unit;

FIG. 18 is a view illustrating modification of the main body unit of the notebook PC corresponding to FIG. 14; and

FIG. 19 is a view illustrating modification of the main body unit of the notebook PC corresponding to FIG. 15.

### DESCRIPTION OF EMBODIMENTS

In the following, embodiments will be described with reference to the accompanying drawings.

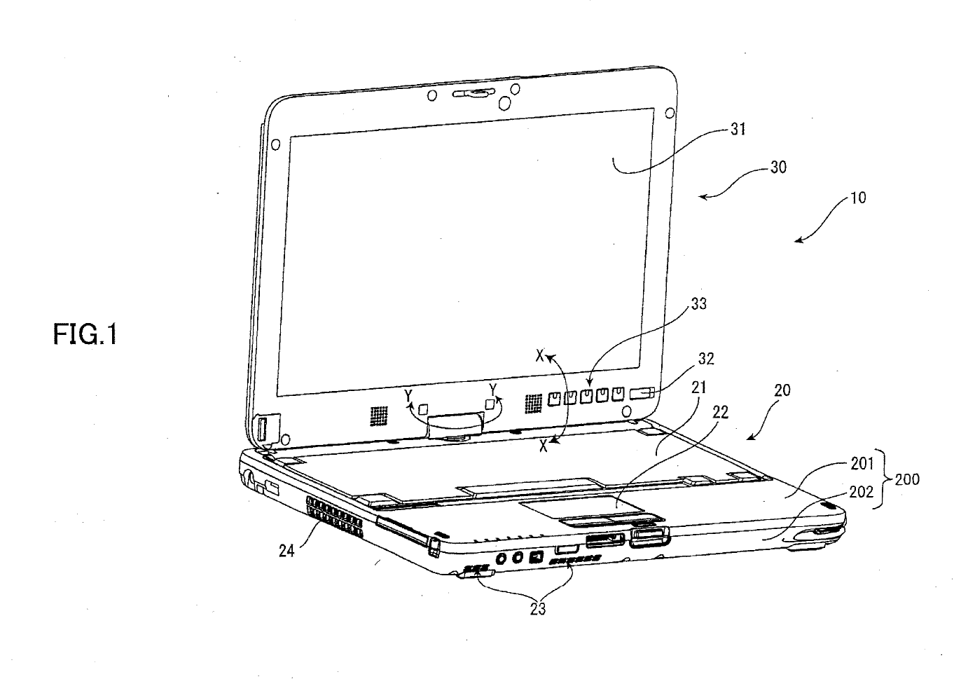

FIG. 1 is an external perspective view illustrating a convertible notebook PC in an open state as an electronic device according to an embodiment.

As illustrated in FIG. 1, a notebook PC 10 includes a main body unit 20 and a display unit 30. The display unit 30 includes a display screen 31 extending over its one of surfaces. The display unit 30 is collapsiblly supported on the main body unit 20 in a direction indicated by a double-sided arrow X-X such that the display unit 30 may be open or closed. The display unit 30 is also rotationally supported on the main body unit 20 in a direction indicated by a double-sided arrow Y-Y when the display unit 30 is in an open state. That is, the display unit 30 has two rotational axes; the direction indicated by the double-sided arrow X-X and the double-sided arrow Y-Y. Thus, the display unit 30 is folded flat on the main body unit 20 from its open state as illustrated in FIG. 1 in the direction indicated by the double-sided arrow X-X with the display screen 31 facing the main body unit 20. Alternatively, the display unit 30 is rotated through 180 degrees from its open state as illustrated in FIG. 1 in the direction indicated by the double-sided Y-Y arrow such that the display unit 30 is folded flat on the main body unit 20 with the display screen 31 facing upward. When the display unit 30 is folded flat on the main body unit 20 with the display screen 31 facing upward, the notebook PC is utilized as a tablet PC (i.e., so-called a “straight-type PC”).

The main body unit 20 of the notebook PC 10 includes a case 200 formed of a top surface member 201, a bottom surface member 202, and a side surface formed along peripheries of the top surface member 201 and the bottom surface member 202. Thus, the top surface member 201, the bottom surface member 202, and the side surface form an internal space of the case 200. The case 200 of the main body unit 20 incorporates a printed circuit board on which a CPU is mounted, and the HDD for storing programs, and various arithmetic processes may be performed by causing the CPU to execute the programs. The top surface of the main body unit 20 includes a keyboard 21 and a touch panel 22. Further, a front-end surface of the main body unit 20 includes air intake ports 23 configured to introduce air into the case 200 of the main body unit 20, and a left-side surface of the main body unit 20 includes an air outlet port 24 configured to discharge air from the case of the main body unit 200. The main body unit 20 further includes various components such as various connectors other than the above-described components.

The display unit 30 includes the aforementioned display screen 31, a power switch 32 and other functional buttons.

Below, a comparative example of a notebook PC is described prior to the detailed description of the notebook PC according to the embodiment.

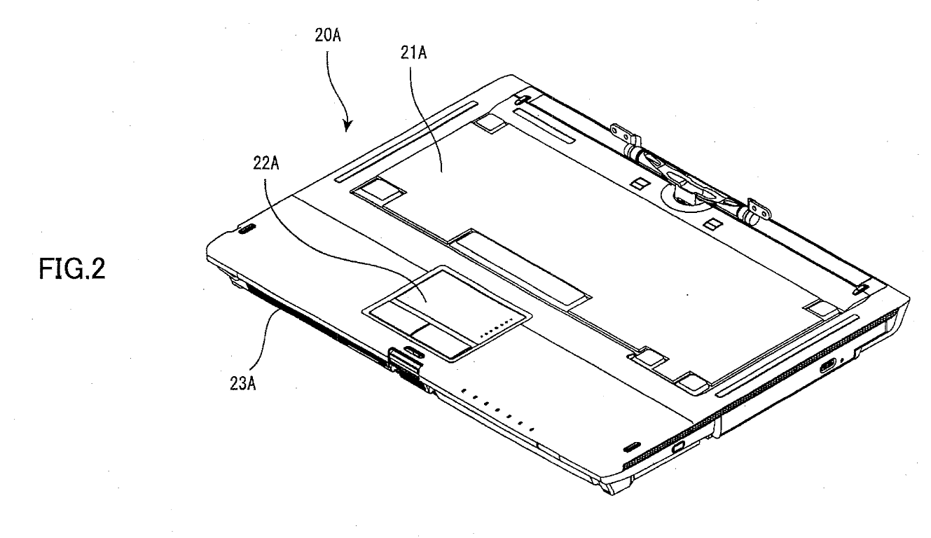

FIG. 2 is an external perspective view illustrating a main body unit of the notebook PC according to the comparative example.

The main body unit 20A of the notebook PC according to the comparative example includes a key board 21A and a touch pad 22A formed on a top surface of the main body unit 20A and air intake ports 23A (not illustrated in FIG. 2) formed in a front-end surface of the main body unit 20A.

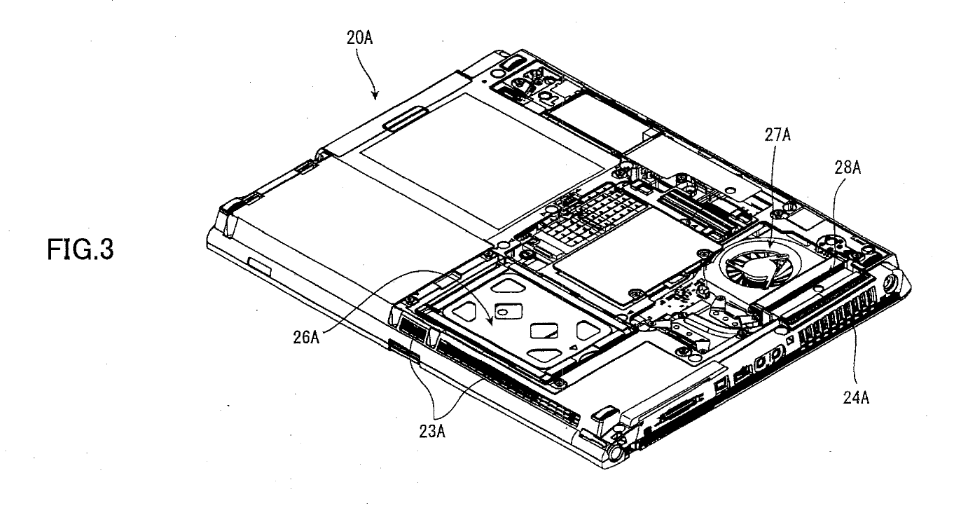

FIG. 3 is a bottom side perspective view illustrating the main body unit 20A of the notebook PC according to the comparative example. FIG. 3 illustrates internal components revealed by removing the bottom surface member of the main body unit 20A.

FIG. 3 illustrates, in addition to the air intake ports 23A, an air outlet port 24A is formed in a side surface (i.e., the left-side surface not illustrated in FIG. 2) of the case.

Further, a HDD 26A is arranged near the air intake ports 23A. Moreover, a set of radiator fins 28A are arranged near the air outlet port 24A, and a fan 27A is arranged such that the set of the radiator fins 28A is sandwiched between the fan 27A and the air outlet port 24A. The fan 27A is configured to suction air from an upper side and a lower side of the fan 27A and discharge the air from a side surface at which the radiator fins 28A reside. The radiator fins 28A come in contact with a not-illustrated CPU-LSI. The CPU-LSI is a large-scale integrated (LSI) circuit incorporating a CPU. The CPU-LSI includes an arithmetic function to execute a program. Accordingly, the CPU-LSI generates a large amount of heat while carrying out the arithmetic operations. The heat generated by the CPU-LSI is transferred to the radiator fins 28A. The heat transferred to the radiator fins 28A is further transferred to the air while the air discharged from the fan 27A passes through intervals between the radiator fins 28A. The air warmed up by the heat transfer is discharged via the air outlet port 24A outside the case of the main body unit 20A. The fan 27A is also configured to cool the ambient air of components residing in an airflow path from the air intake ports 23A to the fan 27A as well as removing the heat transferred to the radiator fins 28A. Specifically, though not as much as the CPU-LSI, the HDD 26A generates heat while rotating a motor mounted on the HDD 26A. Further, due to the motor mounted on the HDD 26A, the HDD 26A generally has a shorter lifespan compared to those of other electronic components. Thus, it is preferable to cool the HDD 26A as much as possible because the lifespan of the HDD 26A may be extended by cooling the HDD 26A.

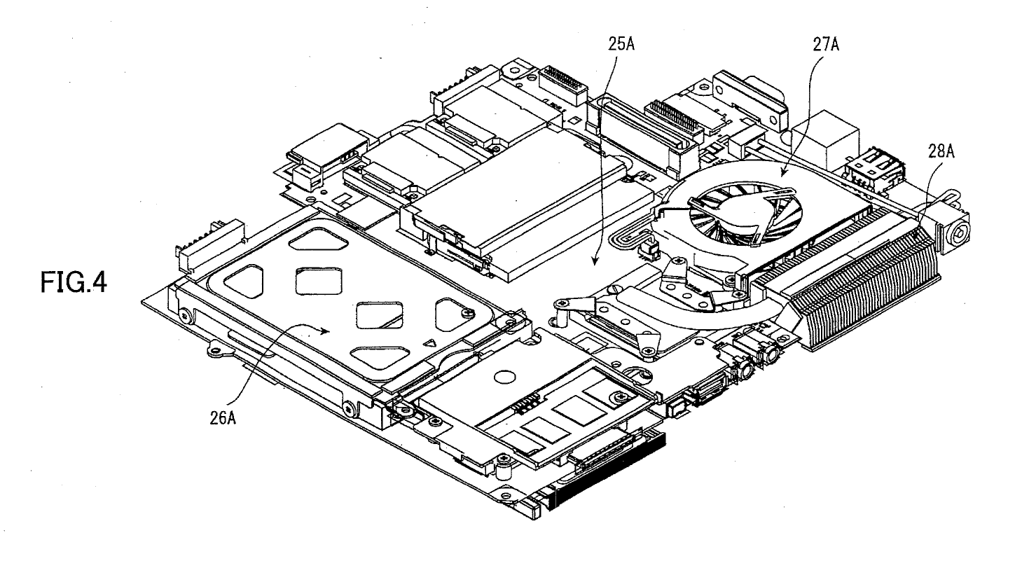

FIG. 4 is a perspective view illustrating a main board and various components fixed to the main board 25A as one of internal components arranged in the main body unit 20A of the notebook PC according to the comparative example in FIG. 3.

As illustrated in FIG. 4, the HDD 26A, the fan 27A and a set of the radiator fins 28A are all mounted on the main board 25A, which is utilized as the printed circuit board.

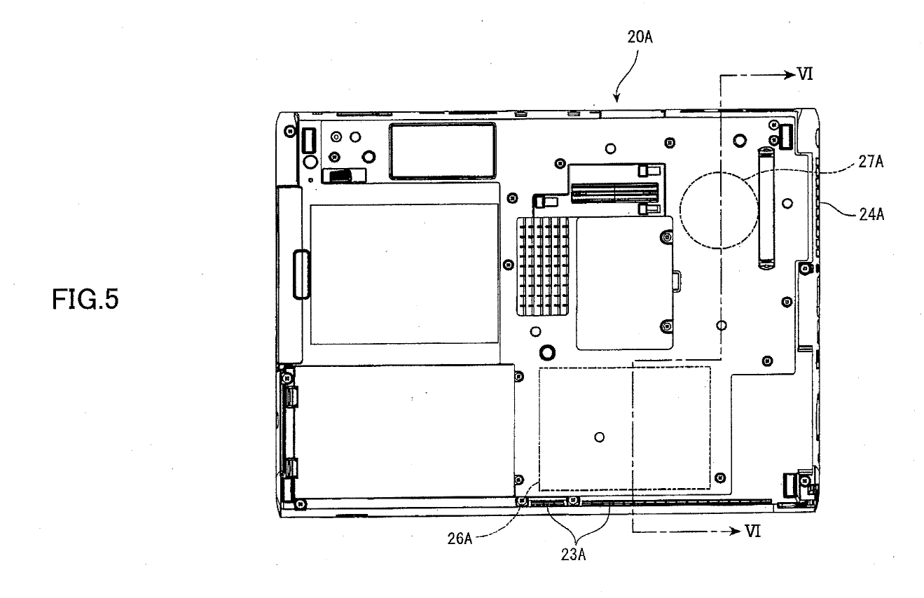

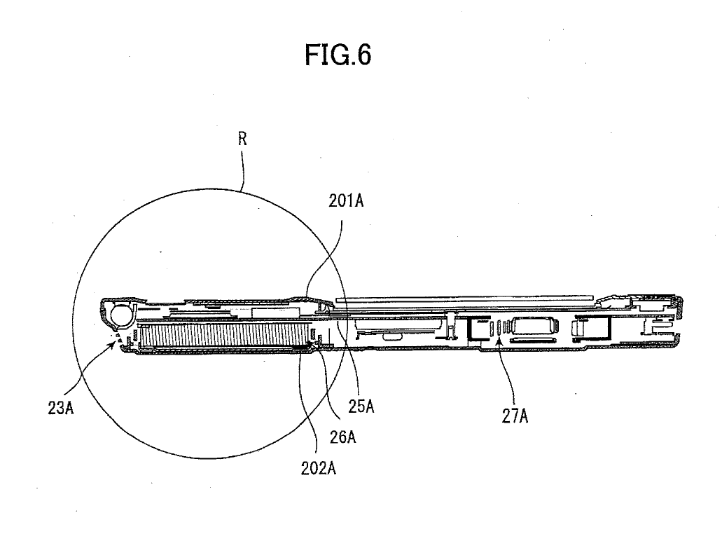

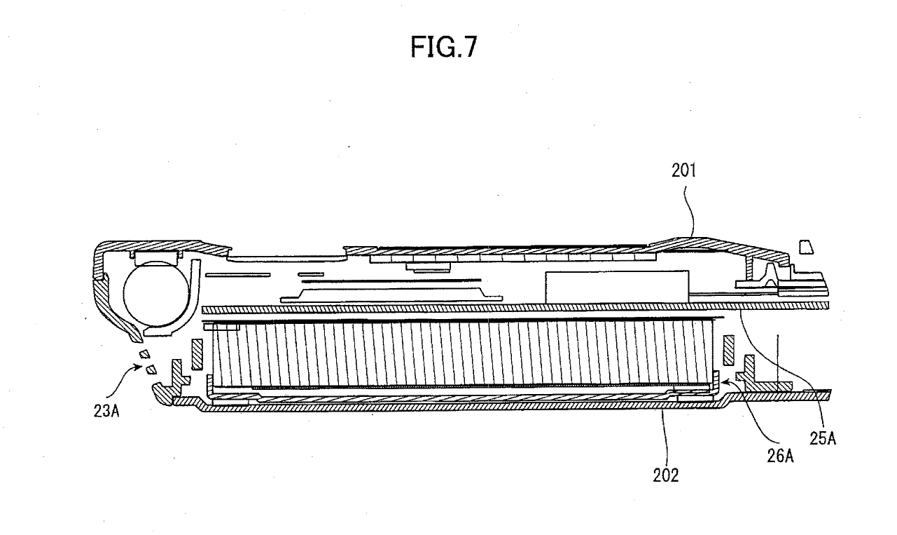

FIG. 5 is a bottom view illustrating the main body unit 20A of the notebook PC according to the comparative example. FIG. 6 is a cross sectional view illustrating the main body unit 20A of the notebook PC according to the comparative example taken along a VI-VI dashed-dotted arrow of FIG. 5, and FIG. 7 is an enlarged view illustrating a part specified by a circle R in FIG. 6.

As illustrated in FIGS. 6 and 7, the HDD 26A is arranged adjacent to the air intake ports 23A formed in the front-end surface. The front-end surface is a part of a side periphery of the case of the main body unit 20A. Further, the HDD 26A is arranged adjacent to an internal bottom wall formed of a bottom surface member 202A of the case in a thickness direction of the case. The main board 25A is formed such that the main board 25A extends along the bottom surface of the case. Accordingly, the HDD 26A is sandwiched between the main board 25A and the bottom surface of the case in a depth direction, in this configuration, of the main body unit 20A. Further, the air intake ports 23A are formed in the front-end surface of the case at a position closer to the bottom surface of the case than closer to the main board 25A.

Since the comparative example of the notebook PC has the above-described configuration, the air suctioned via the air intake ports 23A by the rotation of the fan 27A may need to pass through a narrow space along a whole width of the HDD 26A, between the HDD 26A and the main board 25A, in a cross sectional direction as illustrated in FIGS. 6 and 7. Accordingly, the air suctioned via the air intake ports 23A has high resistance while passing through the narrow space along the whole width of the HDD 26A, between the HDD 26A and the main board 25A. Thus, most of the air suctioned from the air intake ports 23A bypasses the HDD 26A. Thus, although the HDD 26A is arranged adjacent to the air intake ports 23A, air-cooling efficiency may be extremely low in the comparative example of the notebook PC.

Next, the description is given again of the notebook PC according to the embodiment based on the above-described comparative example of the notebook PC.

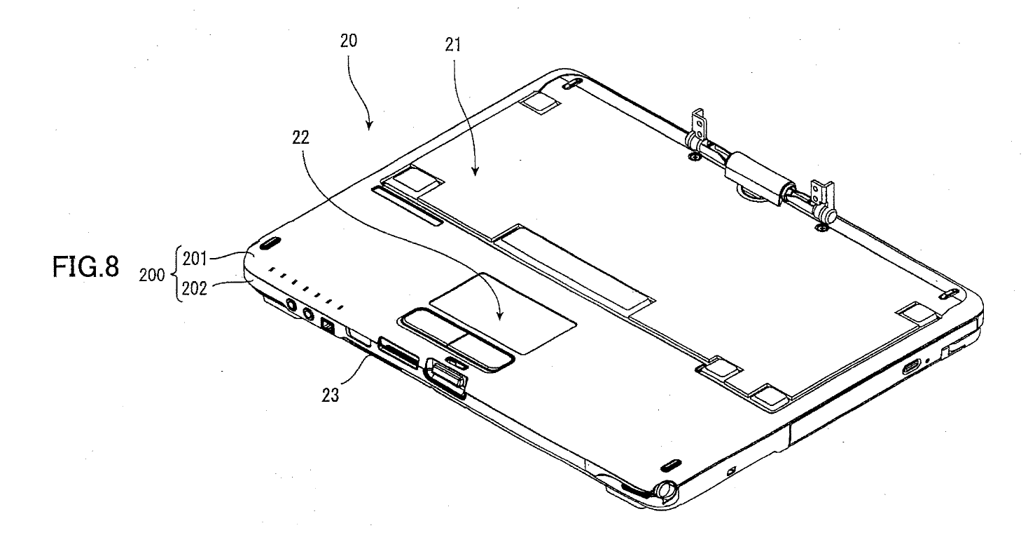

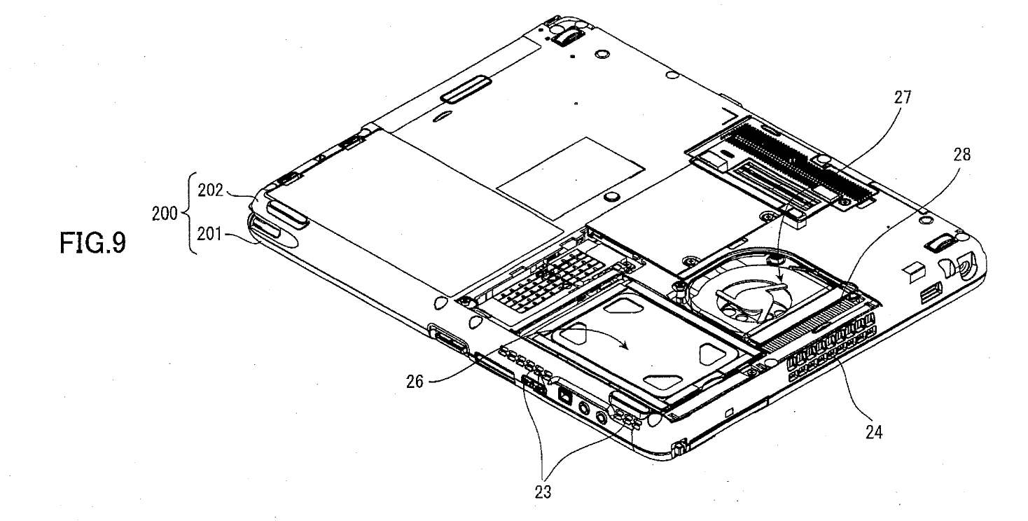

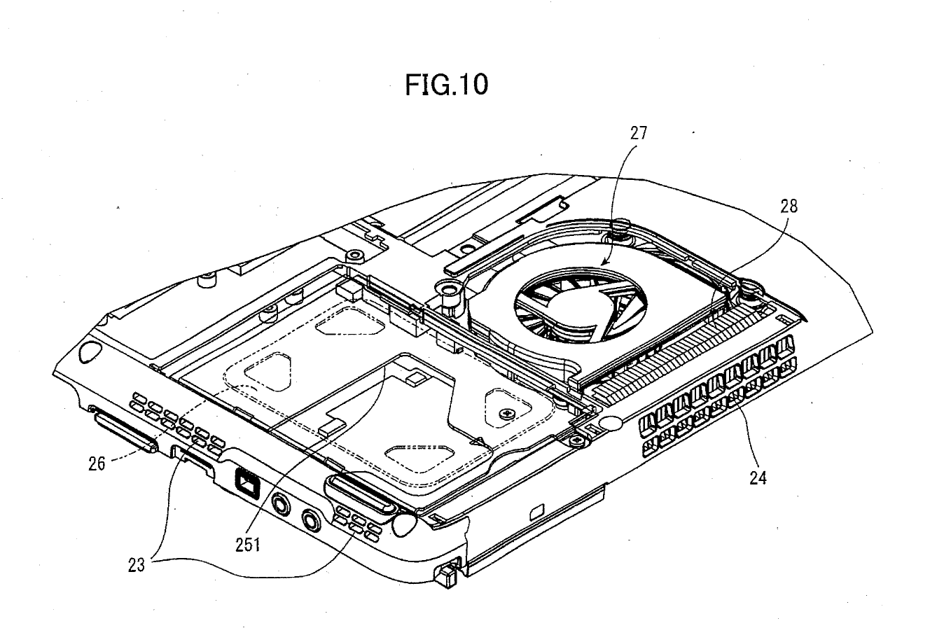

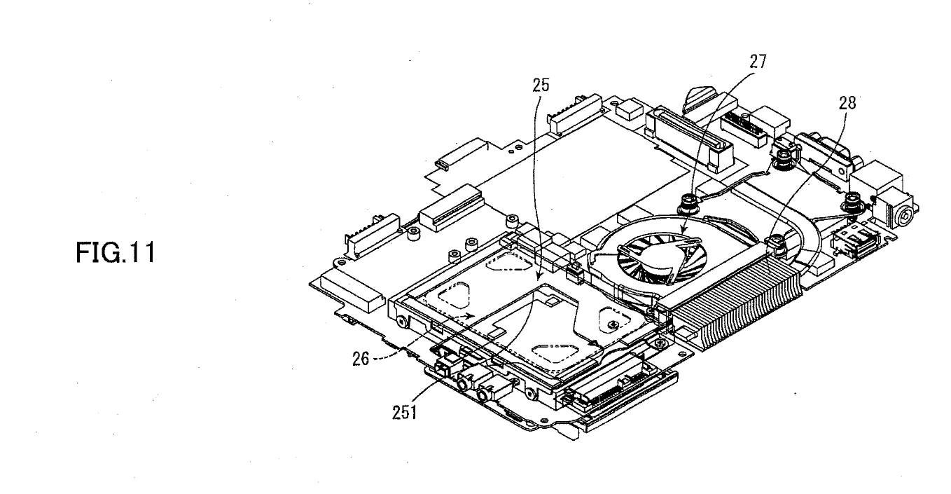

FIGS. 8 and 9 respectively are perspective views illustrating a top surface and a bottom surface of the main body unit of the notebook PC according to the embodiment the external view of which is illustrated in FIG. 1. FIG. 9 illustrates internal components revealed by removing part of the bottom surface member 202 of the main body unit 20. FIG. 10 is an enlarged view illustrating a part including the HDD 26 and the fan 27 taken from the main body unit 20 of the notebook PC according to the embodiment illustrated n FIG. 9. Further, FIG. 11 is a view illustrating the main board 25 and various components fixed to the main board 25 as one of internal components utilized as the printed circuit board arranged in the main body unit 20 of the notebook PC according to the embodiment. FIGS. 10 and 11 illustrate configurations where the HDD 26 is removed from the main board 25, and a phantom line (dashed-two dotted line) in FIG. 10 illustrates a position to which the HDD 26 is arranged.

As illustrated in FIG. 8, the main body unit 20 includes the keyboard 21 and the touch pad 22 arranged on the top surface of the main body unit 20 and the air intake ports 23 are formed in the front-end surface of the main body unit 20 similar to the main body unit 20 illustrated in FIG. 1.

FIG. 9 illustrates, in addition to the air intake ports 23, the air outlet port 24 formed in the side surface of the case of the main body unit (see FIG. 1). Further, a HDD 26 is arranged near the air intake ports 23. Moreover, a set of radiator fins 28 are arranged near the air outlet port 24, and a fan 27 is arranged such that the set of the radiator fins 28 is sandwiched between the fan 27 and the air outlet port 24. Specifically, the fan 27 is arranged such that the HDD 26 is sandwiched between the fan 27 and the front-end surface of the case in which the air intake ports 23 are formed. As illustrated in FIG. 10, the HUD 26, the fan 27 and the set of the radiator fins 28 are all mounted on the main board 25. The fan 27 is configured to suction air from an upper side and a lower side of the fan 27 and discharge the air from a side surface at which the radiator fins 28 reside. Further, a not-illustrated CPU-LSI is arranged on the main board 25 at a position sandwiched between the main board 25 and the radiator fins 28. The CPU-LSI is a large-scale integrated (LSI) circuit incorporating a CPU. The CPU-LSI includes an arithmetic function to execute a program. Accordingly, the CPU-LSI generates a large amount of heat while carrying out the arithmetic operations. The heat generated by the CPU-LSI is transferred to the radiator fins 28. The heat transferred to the radiator fins 28 is further transferred to the air while the air discharged from the fan 27 passes through intervals between the radiator fins 28. The air warmed up by the heat transfer is discharged via the air outlet port 24 outside the case of the main body unit 20. The fan 27 is also configured to cool ambient air of components residing in an airflow path from the air intake ports 23 to the fan 27 as well as removing the heat transferred to the radiator fins 28.

As illustrated in FIGS. 10 and 11, a first vent opening 251 is formed in a part of the main board 25 overlapped with the HDD 26.

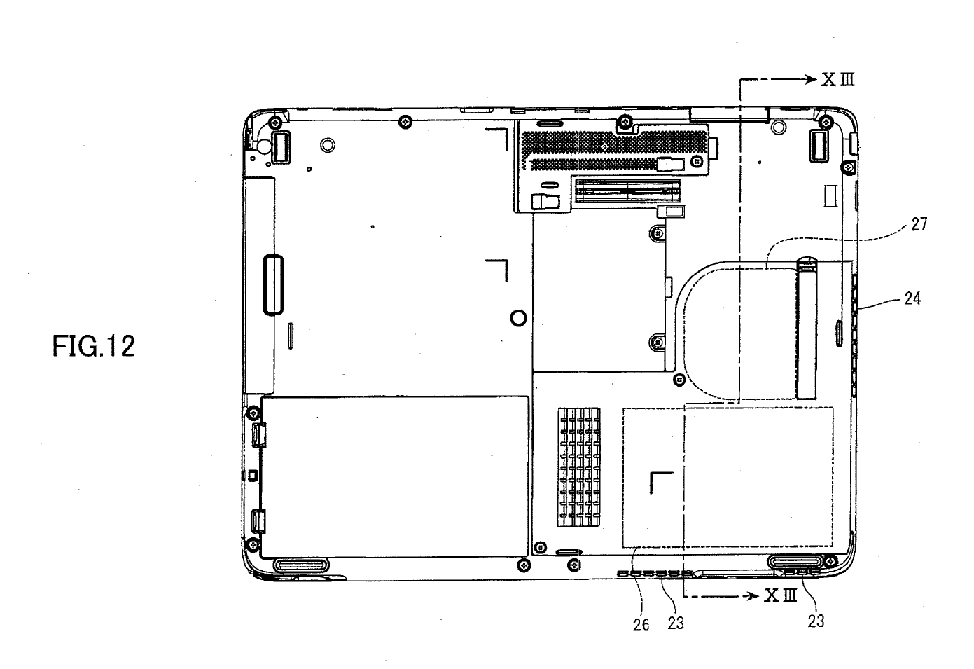

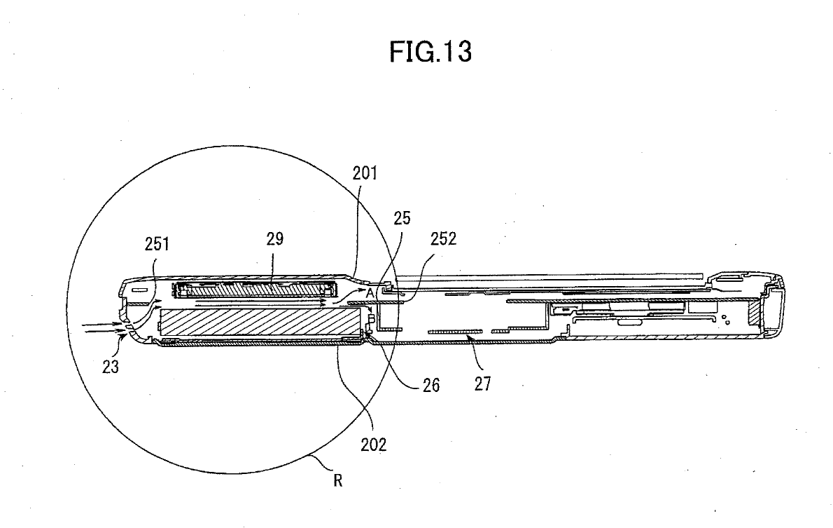

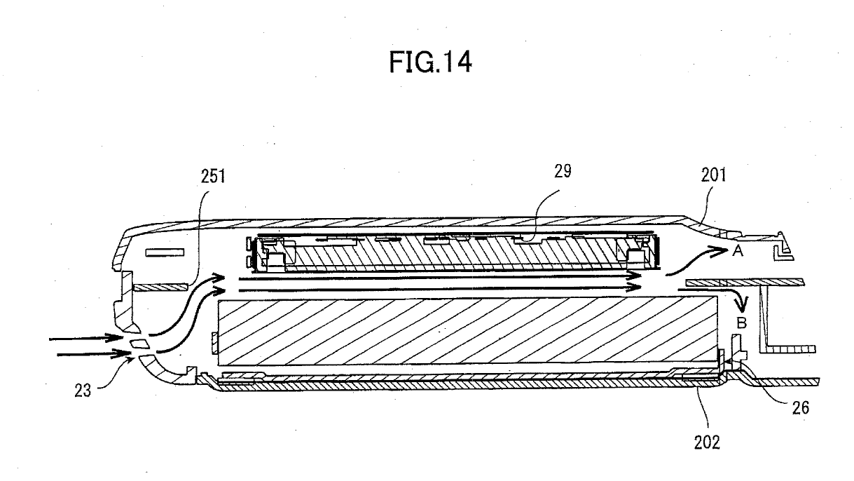

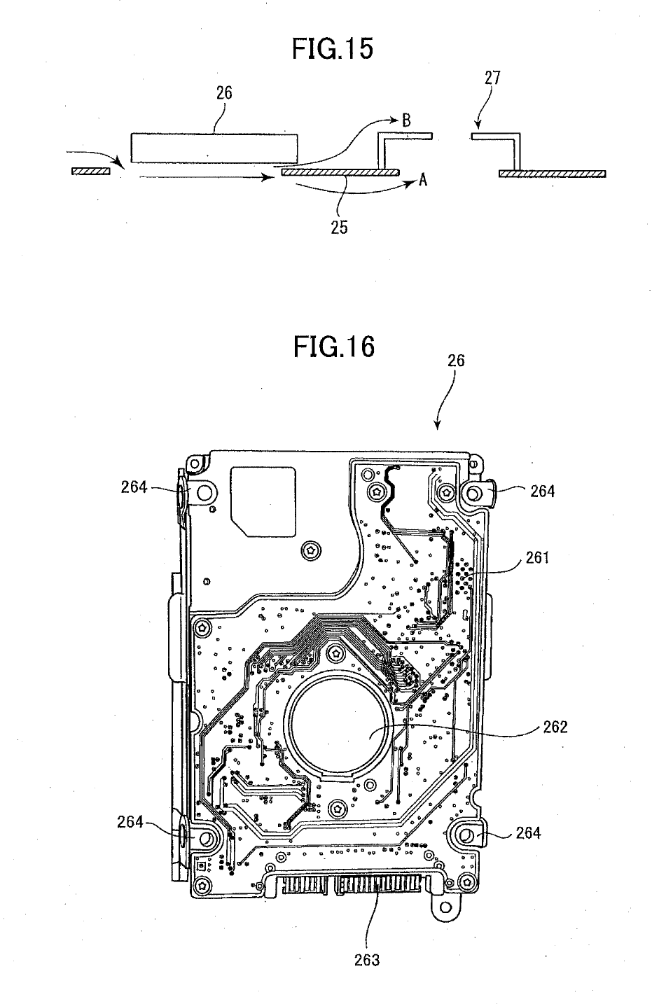

FIG. 12 is a bottom view illustrating the main body unit 20 of the notebook PC according to the embodiment. FIG. 13 is a cross sectional view illustrating the main body unit 20 of the notebook PC according to the embodiment along a XIII-XIII dashed-dotted arrow of FIG. 12, and FIG. 14 is an enlarged view illustrating a part specified by a circle R in FIG. 13. FIG. 15 is a schematic view illustrating airflow in the cross sections of the main body unit 20 illustrated in FIGS. 13 and 14.

As illustrated in FIGS. 13 and 14, the HDD 26 is arranged adjacent to the air intake ports 23 formed in the front-end surface of the case of the main body unit 20. The front-end surface is a part of a side periphery of the case of the main body unit 20. Further, the HDD 26 is arranged adjacent to a bottom surface of the case formed of a bottom surface member 202 in a thickness direction of the case. The main board 25 extends along the bottom surface of the case including a position adjacent to the front-end surface or in contact with the front-end surface, in which the air intake ports 23 are formed such that the HDD 26 is sandwiched between the main board 25 and the bottom surface of the case in a depth direction. Further, the air intake ports 23 are formed in the front-end surface of the case at a position closer to the bottom surface of the case than closer to the main board 25.

Note that as illustrated in FIGS. 13 and 14, a first vent opening 251 is formed in the part of the main board 25, which is also illustrated in FIGS. 10 and 11. The first vent opening 251 is formed such that the first vent opening 251 extends from a position of the main board 25 overlapped with the HDD 26 to a position of the main board 25 closer to the front-end surface than the HDD 26; that is, to a position closer to the air intake ports 23 side. Further, a card connector 29, to which a PC card is attached, is arranged above the HDD 26 such that the first vent opening 251 is sandwiched between the card connector 29 and the HDD 26.

Further, a second vent opening 252 is formed in a part of the main board 25 overlapped with the fan 27.

With this configuration, the air suctioned from the air intake ports 23 passes through the first vent opening 251 and then flows between the HDD 26 and the PC card connector 29. A part of the air that has passed through an interval between the HDD 26 and the PC card connector 29 flows in a direction indicated by an arrow “A” such that the part of the air is suctioned via the second vent opening 252 by the fan 27. The other part of the air that has passed through the interval between the HDD 26 and the PC card connector 29 flows in a direction indicated by an arrow “B” such that the other part of the airflow is suctioned via the bottom side of the case by the fan 27. As described earlier, the air suctioned by the fan 27 is discharged from the radiator fins 28 side (see FIG. 10 as an example), the discharged air absorbs the heat of the radiator fins 28 while passing through intervals between the radiator fins 28, and the air passed through the intervals between the radiator fins 28 is then discharged outside via the air outlet port 24. With this configuration, the air may efficiently flow along the HDD 26 to effectively cool the HDD 26 in this embodiment.

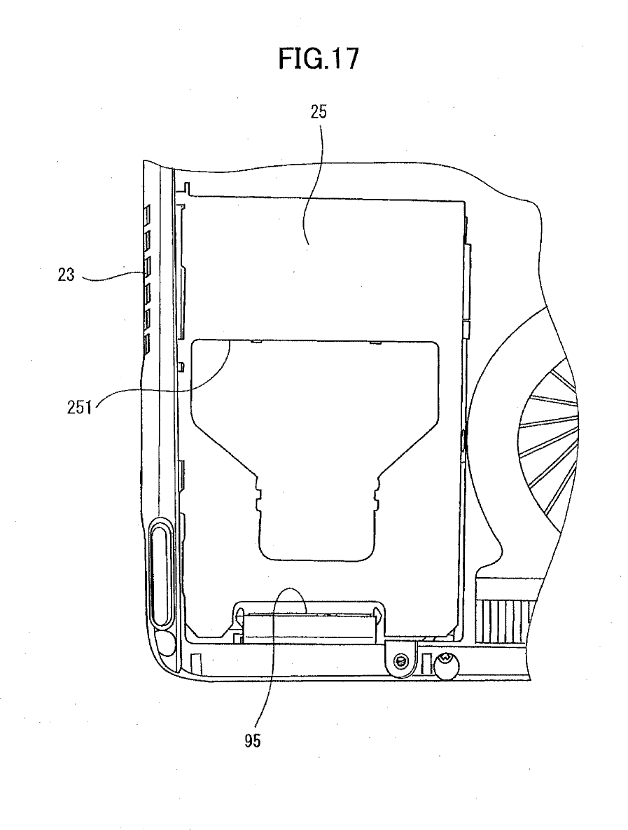

FIG. 16 is a view illustrating a bottom surface of the HDD 26, and FIG. 17 is a view illustrating an area in which the HDD 26 is arranged inside the case of the main body unit 20.

The bottom surface of the HDD 26 illustrated in FIG. 16 faces the main board 25 side when the HDD 26 is arranged in a HDD arrangement area illustrated in FIG. 17. The bottom surface of the HDD 26 includes a HDD circuit board 261 extending along the bottom surface of the HDD 26, and a motor 262 is arranged approximately at a central position of the bottom surface that is overlapped with an opening formed in the HDD circuit board 261. The motor 262 is configured to rotate a not-illustrated hard disk that is incorporated as a recording medium in the HDD 26. In the HDD 26, a large amount of heat is generated by the motor 262, and the lifespan of the motor 262 is highly associated with the lifespan of the HDD 26. Accordingly, it is preferable to cool the motor 262 as much as possible to increase the lifespan of the motor 262. Further, a connector 263 is provided on a side of the HDD 26 as illustrated in FIG. 16. The connector 263 is connected to a connector 95 provided on a side of the HDD arrangement area when the HDD 26 is arranged in the HDD arrangement area illustrated in FIG. 17. The HDD 26 is screwed by four screw clamps 264 provided at four corners of the HDD 26.

The main board 25 is arranged such that the main board 25 extends along the HDD arrangement area illustrated in FIG. 17, and the first vent opening 251 is formed in the main board 25. A part of the first vent opening 251 formed in the main board 25 at a position closer to the air intake ports 23 is distant from the area of the main board 25 overlapped with the HDD 26 as illustrated in FIGS. 13 and 14. The part of the first vent opening 251 further extends closer to the air intake ports 23. Note that in view of the airflow path, it is preferable that the first vent opening 251 be formed as widely as possible. However, it is not preferable that the first vent opening 251 be unnecessarily wide in view of wiring space on the main board 25. Note that the heat generated in the HDD 26 is caused by the rotation of the motor 262, and hence, the first vent opening 251 may extend to an area of the main board 25 that is overlapped with the motor 262.

Note that the HDD circuit board 261 extends along the bottom surface of the HDD 26 as illustrated in FIG. 16. The HDD 26 is screwed via the screw clamps 264 to be fixed to the main board 25. Thus, the screw clamps 264 come in contact with the main board 25 while the HDD circuit board 261 is not in contact with the main board 25. However, the part of the main board 25 overlapped with the HDD 26 may be further provided with an insulator sheet. If the insulator sheet is provided in the overlapped part of the HDD 26, the wires arranged on the main board 25 may be reliably insulated from the wires arranged on the HDD circuit board 261 provided on the bottom surface of the HDD 26. When the insulator sheet is provided on the main board 25, the insulator sheet may also include a vent opening having a shape similar to that of the first vent opening 251 formed in the main board 25.

Next, modification of the first vent opening 251 formed in the main board 25 is described below.

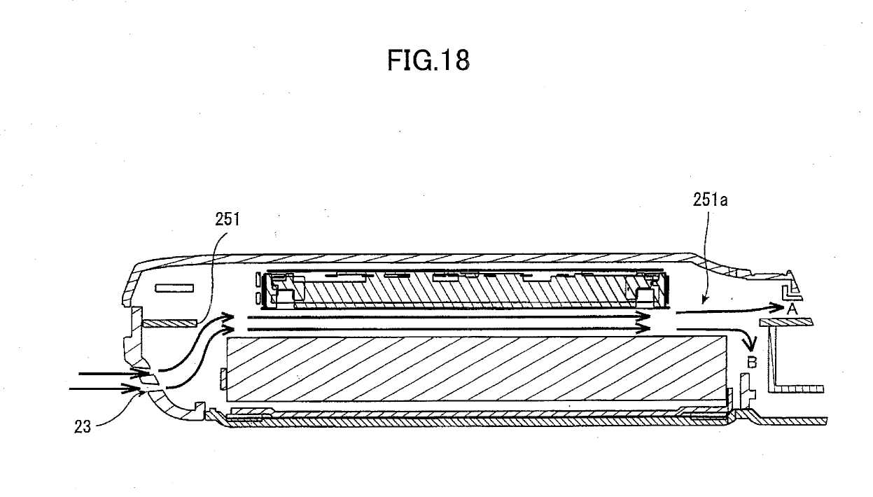

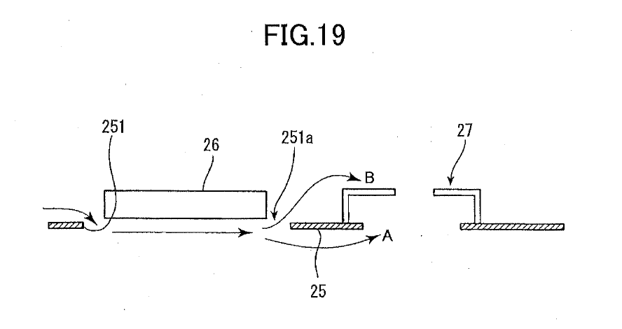

FIGS. 18 and 19 are views illustrating modification of the main body unit of the notebook PC according to the embodiment corresponding to FIGS. 14 and 15.

In the main body unit of the notebook PC according to the embodiment, the first vent opening 251 formed in the main board 25 extends further to a position more distant from the air intake ports 23 side than from the area overlapped with the HDD 26. However, the first vent opening 251 formed in the main board 25 extends only up to the area overlapped with the fan 27 side that is distant from the air intake ports 23.

By contrast, in the modification of the main body unit of the notebook PC illustrated in FIGS. 18 and 19, the first vent hole 251 formed in the main board 251 extends to the air intake ports 23 side from the area overlapped with the HDD 26. In addition, the first vent hole 251 formed in the main board 251 further includes an extending area 251a that extends further closer to the fan 27 side from the HDD 26; that is, the extending area 251a extends to a position having a distance from the air intake ports 23 longer than from the HDD 26. If the first vent opening 251 formed in the main board 25 extends farther away from the position of the HDD 26, the airflow may more efficiently pass through an upstream side and a downstream side of the HDD 26. Accordingly, the HDD 26 may be cooled by the airflow more effectively.

Note that in this embodiment and the modification, the HDD is illustrated as an example of the electronic component. However, the electronic component may not be limited to the HDD. The configurations of the embodiment and the modification may be applied to any electronic components that are arranged at a position in the airflow path and overlapped with the main board.

Further, the notebook PC is according to an example of the electronic device according to the embodiment and the modification. However, the embodiment and the modification may be applied to any electronic devices that may need to be cooled by airflow.

In the disclosed electronic device according to the embodiment and the modification, the electronic component arranged adjacent to the circuit board (i.e., the main board) may be effectively cooled.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that the various changes, substitutions, and alterations could be made hereto without departing from the spirit and scope of the invention.

What is claimed is:

1. An electronic device, comprising:
a case having a first surface facing a second surface and a side surface formed along peripheries of the first surface and the second surface, the first surface, the second surface and the side surface forming an internal space of the case;
an electronic component arranged inside the case at a position adjacent to a first side part of the side surface of the case, a gap being provided between the electronic component and the first side part; and
a circuit board extending along the first surface of the case to include a position adjacent to or in contact with the first side part of the case, the circuit board having a distance from the first surface of the case such that the electronic component is sandwiched between the circuit board and the first surface of the case, wherein
the case includes an air intake port configured to introduce air into the case, the air intake port being formed in the first side part of the side surface at a position closer to the first surface thereof than the circuit board, and an air outlet port configured to discharge from the case the introduced air having flowed along the electronic component, and
the circuit board includes a first vent opening including a first end portion extending to a position closer to the first side part of the case than a first end of the electronic component facing the first side part of the case.

2. The electronic device as claimed in claim 1, wherein
the first vent opening includes the first end portion extending to a position closer to the first side part of the case than the first end of the electronic component facing the first side part of the case,
the first vent opening further includes a second end portion extending to a position distant from a second end of the electronic component, the second end of the electronic component having a distance from the first side part of the case longer than the first end of the electronic component.

3. The electronic device as claimed in claim 1, wherein
the circuit board further includes a fan on a first surface of the circuit board facing the first surface of the case such that the fan is arranged at a position the same as the electronic component between the first surface of the circuit board and the first surface of the case, and
the circuit board further includes a second vent opening formed at a position overlapped with the fan, the second vent opening being configured to introduce air to flow along a second surface of the circuit board facing the second surface of the case.

4. The electronic device as claimed in claim 1, wherein
the electronic component is a hard disk drive incorporating a motor configured to rotationally drive a built-in hard disk such that the hard disk drive accesses the built-in hard disk while rotationally driving the built-in hard disk.

5. The electronic device as claimed in claim 4, wherein
the first vent opening formed in the circuit board extends to a position overlapped with the motor of the hard disk drive.

6. The electronic device as claimed in claim 1, further comprising:
a main body unit including the case, the electronic component and the circuit board, the main body unit being configured to execute arithmetic processes; and a display unit including a display screen, the display unit being collapsiblly connected to the main body unit.
